(19) United States
(12) Patent Application Publication
(10) Pub. No.: US 2026/0314125 A1
(43) Pub. Date: Oct. 8, 2026

(54) FILTER STRUCTURES FOR REDUCING FULL WIDTH HALF MAXIMUMS IN LIGHT-EMITTING DIODE DEVICES

(71) Applicant: CreeLED, Inc., Durham, NC (US)

(72) Inventors: Joseph G. Sokol, Durham, NC (US); Michael Check, Holly Springs, NC (US); David Suich, Durham, NC (US); Colin Blakely, Raleigh, NC (US); Robert Wilcox, Rolesville, NC (US); Andre Pertuit, Raleigh, NC (US)

(21) Appl. No.: 19/098,410

(22) Filed: Apr. 2, 2025

(51) Int. Cl. H10H 20/851

(52) U.S. Cl. CPC H10H 20/851

(57) ABSTRACT

Solid-state lighting devices and more particularly filter structures for reducing full width half maximum (FWHM) values of spectral outputs in light-emitting diode (LED) devices are disclosed. Filter structures are configured to receive light from an LED chip having a first FWHM value and provide light that exits the LED chip with a second FWHM value that is less than the first FWHM value. Filter structures embody band-pass filters with midpoints of passbands configured to be the same or similar to peak wavelengths generated by corresponding LED chips. Exemplary LED devices include LED chips, LED packages, and LED displays that incorporate filter structures for reducing FWHM values of targeted emission spectrums.

### FIELD OF THE DISCLOSURE

The present disclosure relates to solid-state lighting devices and more particularly to filter structures for reducing full width half maximums of spectral outputs in light-emitting diode (LED) devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LED technology is increasingly being developed for providing general illumination in a variety of environments. LED manufacturers must balance multiple application tradeoffs including efficacy, longevity, spectral optimization, and optical distribution in view of potential environmental impacts.

The art continues to seek improved LEDs and solid-state lighting devices having desirable illumination characteristics capable of overcoming challenges associated with conventional lighting devices.

### SUMMARY

The present disclosure relates to solid-state lighting devices and more particularly to filter structures for reducing full width half maximum (FWHM) values of spectral outputs in light-emitting diode (LED) devices. Filter structures are configured to receive light from an LED chip having a first FWHM value and provide light that exits the LED chip with a second FWHM value that is less than the first FWHM value. Filter structures embody band-pass filters with midpoints of passbands configured to be the same or similar to peak wavelengths generated by corresponding LED chips. Exemplary LED devices include LED chips, LED packages, and LED displays that incorporate filter structures for reducing FWHM values of targeted emission spectrums.

In one aspect, an LED device comprises: an LED chip configured to generate a first emission spectrum of light having a first peak wavelength and a first full width half maximum value; and a filter structure on the LED chip, the filter structure configured to provide a second emission spectrum of light and a second full width half maximum value that is less than the first full width half maximum value, the second emission spectrum of light being a subset of the first emission spectrum of light. In certain embodiments, the first peak wavelength is in a range from 480 nanometers (nm) to 600 nm. In certain embodiments, the second full width half maximum value is no more than eighty percent of the first full width half maximum value. In certain embodiments, the filter structure comprises a band-pass filter having a midpoint of a passband that is within 5 nm of the first peak wavelength. In certain embodiments, the filter structure is positioned on a top surface of the LED chip and on at least one side surface of the LED chip. In certain embodiments, the filter structure is a first filter structure positioned on a top surface of the LED chip, and a second filter structure is positioned on at least one side surface of the LED chip. In certain embodiments, the LED chip comprises an active LED structure on a carrier such that a p-type layer of the active LED structure is closer to the carrier than an n-type layer of the active LED structure, and the filter structure is on a surface of the n-type layer. In certain embodiments, the LED chip comprises an active LED structure on a growth substrate, and the filter structure is on a surface of the growth substrate. In certain embodiments, the filter structure forms a band-pass filter having a midpoint of a passband that is greater than the second peak wavelength by at least 5 nm. In certain embodiments, the second emission spectrum of light comprises an asymmetric shape.

In another aspect, an LED device comprises: an LED chip configured to generate light of a first peak wavelength; a lumiphoric material arranged to convert at least a portion of the light of the first peak wavelength to light with a second peak wavelength that different than the first peak wavelength, the LED chip and the lumiphoric material providing a first emission spectrum of light having the second peak wavelength and a first full width half maximum value; and a filter structure on the LED chip, the filter structure configured to provide a second emission spectrum of light having a second full width half maximum value that is less than the first full width half maximum value, the filter structure comprising a band-pass filter having a midpoint of a passband that is within 5 nm of the second peak wavelength. In certain embodiments, the second full width half maximum value is no more than fifty percent of the first full width half maximum value. In certain embodiments, the second full width half maximum value is in a range from twenty-five percent to no more than fifty percent of the first full width half maximum value. In certain embodiments, the second peak wavelength is in a range from 480 nm to 650 nm. In certain embodiments, the filter structure comprises a first filter structure portion and a second filter structure portion that are separated by the lumiphoric material. In certain embodiments, the first filter structure portion comprises a short pass filter configured to pass the light of the first peak wavelength and reflect light of the second peak wavelength, and the second filter structure portion comprises a long pass filter configured to pass the light of the second peak wavelength and reflect light of the first peak wavelength. In certain embodiments, the filter structure is positioned on a top surface of the LED chip and on at least one side surface of the LED chip. In certain embodiments, the filter structure is a first filter structure positioned on a top surface of the LED chip, and a second filter structure is positioned on at least one side surface of the LED chip.

In another aspect, an LED device comprises: a printed circuit board; and a plurality of light-emitting diode (LED) packages mounted on the board, at least one LED package of the plurality of LED packages comprising: a first LED chip configured to generate a first emission spectrum of light having a first peak wavelength in a range from 500 nanometers (nm) to 570 nm and a first full width half maximum value; a filter structure on the first LED chip, the filter structure configured to provide a second emission spectrum of light in the range from 500 nm to 570 nm and having a second full width half maximum value that is less than the first full width half maximum value; a second LED chip configured to generate light having a second peak wavelength in a range from 600 nm to 650 nm; and a third LED chip configured to generate light having a third peak wavelength in a range from 430 nm to 480 nm. In certain embodiments, the second full width half maximum value is no more than eighty percent of the first full width half maximum value. In certain embodiments, the filter structure comprises a band-pass filter having a midpoint of a passband that is within 5 nm of the first peak wavelength. In certain embodiments, the LED device comprises an LED display.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of an exemplary light-emitting diode (LED) device with a filter structure according to principles of the present disclosure.

FIG. 1B is a spectral plot of the LED device of FIG. 1A.

FIG. 2A is a cross-sectional view of an LED device that is similar to the LED device of FIG. 1A for embodiments that further include a lumiphoric material.

FIG. 2B is a spectral plot of the LED device of FIG. 2A.

FIG. 2C is a spectral plot of the LED device of FIG. 2A for the configuration where a detectable portion of light from the active LED structure is present in the aggregate emissions.

FIG. 2D is a spectral plot of the LED device of FIG. 2A for a configuration similar to FIG. 2C except the second emission spectrum exhibits broader emissions.

FIG. 3 is a cross-sectional view of an LED device that is similar to the LED device of FIG. 2A for embodiments where the filter structure of FIG. 1A is split into first and second portions.

FIG. 4 is a cross-sectional view of an LED device that is similar to the LED device of FIG. 1A for embodiments where the filter structure extends on a top surface of the LED chip and on side surfaces of the LED chip.

FIG. 5 is a cross-sectional view of an LED device that is similar to the LED device of FIG. 2A for embodiments where the filter structure is positioned on a top surface of the LED chip and a second filter structure is positioned on one or more side surfaces of the LED chip.

FIG. 6 is a cross-sectional view of an LED device that is similar to the LED device of FIG. 1A for embodiments where the active LED structure is inverted.

FIG. 7 is a cross-sectional view of an LED device that is similar to the LED device of FIG. 1A for embodiments where the LED chip is a flip-chip LED.

FIG. 8A is a spectral plot for an LED device similar to the LED device of FIG. 1A except the filter structure of FIG. 1A is configured to provide an asymmetric shape for the second emission spectrum.

FIG. 8B is a spectral plot for an LED device similar to the LED device of FIG. 1A except the filter structure of FIG. 1A is configured to provide another asymmetric shape for the second emission spectrum.

FIG. 9 is a schematic diagram of a portion of an LED device, such as a display screen or LED display, comprising an LED chip or LED package having a filter structure according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices and more particularly to filter structures for reducing full width half maximum (FWHM) values of spectral outputs in light-emitting diode (LED) devices. Filter structures are configured to receive light from an LED chip having a first FWHM value and provide light that exits the LED chip with a second FWHM value that is less than the first FWHM value. Filter structures embody band-pass filters with midpoints of passbands configured to be the same or similar to peak wavelengths generated by corresponding LED chips. Exemplary LED devices include LED chips, LED packages, and LED displays that incorporate filter structures for reducing FWHM values of targeted emission spectrums.

An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may generally include an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer may comprise a single quantum well, a multiple quantum well (MQW), a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that may include many materials, such as sapphire, silicon carbide (SiC), aluminum nitride (AlN), and GaN.

Different embodiments of the active LED structure may emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

An LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, spectral density, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED chip, dispersal in an encapsulant material configured to cover one or more LED chips, and/or coating on one or more optical or support elements (e.g., by powder coating, inkjet printing, spraying, or the like). In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

In certain embodiments, one or more lumiphoric materials may be provided as at least a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In certain embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures of the present disclosure may be formed from a bulk material which is optionally patterned and then singulated. In certain embodiments, wavelength conversion elements and cover structures may comprise a generally planar upper surface that corresponds to a light emission area of the LED package. Wavelength conversion elements and cover structures may be attached to one or more LED chips using, for example, a layer of transparent adhesive. In various embodiments, wavelength conversion elements may comprise configurations such as phosphor-in-glass, ceramic phosphor plate, or single crystal phosphor arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that may be cut or separated into individual wavelength conversion elements.

The present disclosure may be useful for LED chips having a variety of geometries, such as vertical and/or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface. In certain flip-chip embodiments, the growth substrate of the LED chip may form the intended light-exiting surface for the LED chip.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support member, such as a submount or a lead frame structure.

Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB.

Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

As used herein, filter structures may include multiple layers or coatings with variable thickness and/or index of refraction differences that collectively provide the ability to pass certain wavelengths of light while reflecting or otherwise redirecting other wavelengths of light. In certain embodiments, the filter structures may be deposited directly on LED chips. In other embodiments, the filter structures may embody preformed structures that are subsequently attached to LED chips. For example, the filter structure may first be deposited on a support element, such as glass or sapphire that is transparent to visible light, followed by cutting the filter structure to size before attachment to an LED chip. In various arrangements, filter structures as described herein may include one or more of a band-pass filter structure configured to provide light spectrums with reduced FWHM values compared with underlying LED chips or, in some instances, underlying LED chips and lumiphoric materials. Filter structures may include combinations of short-pass filters that reflect higher wavelengths and long-pass filters that reflect shorter wavelengths to effectively narrow wavelengths of the overall spectral output.

By way of non-limiting example, a filter structure may include alternating layers with alternating index of refraction materials (e.g., high-low) where relative layer thicknesses are chosen specifically to promote constructive interference for wavelengths above or below a specific wavelength or for a specific wavelength band while reflecting other wavelengths. Filter structures according to the present disclosure may include but are not limited to one or more oxides of silicon (e.g., SiO₂), oxides of zirconium (e.g., ZrO₂), oxides of aluminum (e.g., Al₂O₃), oxides of titanium (e.g., TiO₂ or Ti₃O₅), oxides of tantalum (e.g., Ta₂O₅), oxides of indium (e.g., In₂O₃), indium tin oxide (ITO), silicon nitride (e.g., SiNₓ), magnesium fluoride (e.g., MgF₂), cerium fluoride (e.g., CeF₃), lanthanum fluoride (e.g., LaF₃), aluminum fluoride (e.g., AlF₃) fluoropolymers, and combinations thereof.

An emission spectrum for an LED device may be represented by a spectral plot of intensity or amplitude versus wavelength. The FWHM is a well-defined term corresponding to the width of the spectral curve at half the maximum amplitude. The FWHM value for a given LED is useful for characterizing a spread of wavelengths in the corresponding emission spectrum. FWHM values vary for different types of LED chips, depending on the emission wavelengths and/or the material type of the active LED structure. In the example of GaN-based active LED structures common for blue and green emitting LED chips, the indium composition of InGaN in MQW structures increases with increased wavelength, such as from blue LEDs to green LEDs. However, the increased indium content also increases the lattice constant mismatch with bulk GaN of other portions of the LED chip. This larger mismatch leads to increased strain and exhibits a broader emission profile or a larger FWHM.

According to aspects of the present disclosure, filter structures are provided that effectively reduce FWHM values in emission spectra of LED devices. For example, an LED chip may be configured to generate light having a first peak wavelength with a first FWHM. A filter structure may be positioned in the light path of the LED chip that effectively reduces the first FWHM to a lower second FWHM. The filter structure may be configured so that the reduction in FWHM occurs with little or no change to the peak wavelength. In other applications, the filter structure may be configured with a band-pass that is offset from the peak wavelength to provide an asymmetric spectral output.

In certain applications, narrower FWHM values according to principles of the present disclosure are important for providing increased color purity and/or color rendering at specific wavelengths. A lower FWHM value means a smaller distribution of wavelengths, thereby positioning the color point closer to the boundary of the spectral locus in a CIE chromaticity diagram for a given wavelength. For monochromatic lighting applications, such as airport runway threshold lights, lower FWHM values will reduce overlap in shoulder emissions of different peak wavelengths, thereby providing improved perception of colors. In some instances, reduced overlap may provide improved perception for individuals with color blindness. In multiple-color applications where multiple LEDs of different emission wavelengths are combined, increasing the color purity of one or more of the emission wavelengths will increase a color gamut for the aggregate emissions. For example, a pixel of an LED display may be formed by a cluster of red, green, and blue LED chips, where one or more have filter structures for reducing FWHM values. In wavelength-converted devices, such as blue LED chips with recipient lumiphoric materials, aggregate emissions sometimes have multiple peaks, corresponding to the LED chip and/or different energy states of the lumiphoric material. Filter structures may be implemented to reduce multiple peaks and/or reduce FWHM values of broader lumiphoric emissions.

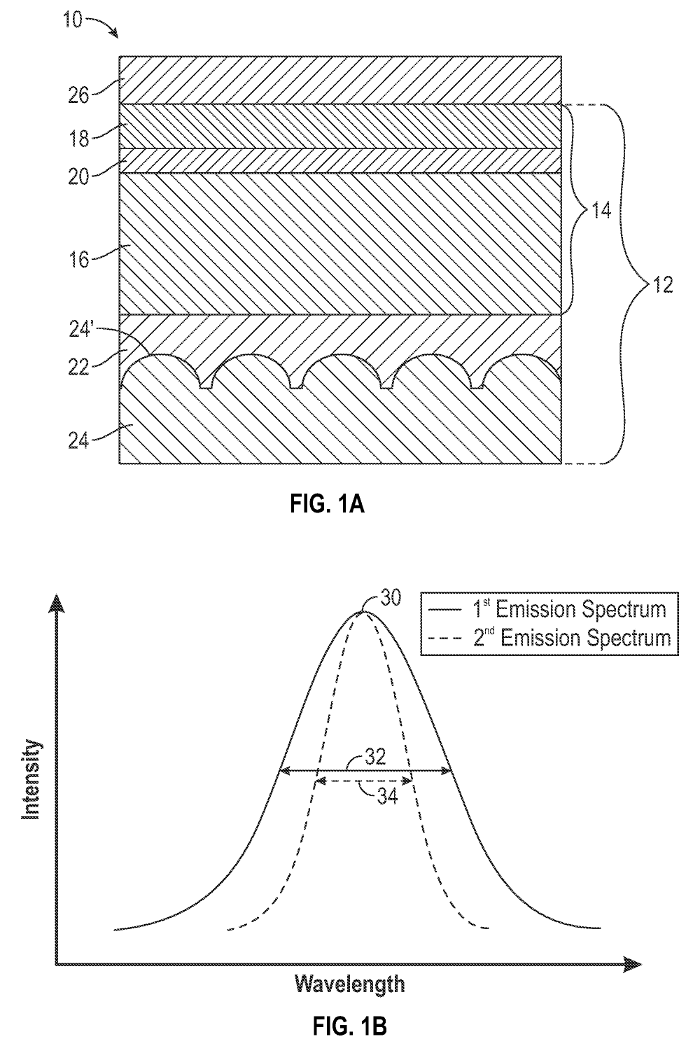

FIG. 1A is a cross-sectional view of an exemplary LED device 10 according to principles of the present disclosure. The LED device 10 may generally represent elements of an LED package or alternatively a chip-level device that is subsequently positioned in an LED package. The LED device 10 includes an LED chip 12 configured to generate light having a first peak wavelength. The LED chip 12 generally includes an active LED structure 14 formed by at least one n-type layer 16, at least one p-type layer 18, and an active layer 20 therebetween. The active LED structure 14 is formed on a substrate 24, such as a growth substrate on which the active LED structure 14 may be epitaxially grown. In certain embodiments, the substrate 24 may include a patterned surface 24’ that promotes increased light extraction. In still further embodiments, at least one buffer layer 22, such as an undoped buffer layer, may be formed on the substrate 24 to provide a suitable growth surface for the active LED structure 14. The material composition and structure of the active layer 20 determines a bandgap and corresponding first peak wavelength generated by the LED chip 12. Additionally, a first emission spectrum generated by the LED chip 12 includes a first FWHM value that is also determined by the material composition and structure of the active layer 20. As described above, the FWHM value generally increases for longer wavelength emissions, such as green emissions in a range from 500 nm to 570 nm by way of example. A filter structure 26 is provided on the LED chip 12 in an intended light emission direction. The filter structure 26 is configured as a band-pass filter that may be generally centered on the first peak wavelength of the LED chip 12, but with a band-pass that provides a second FWHM that is lower than the first FWHM. Accordingly, a second emission spectrum of light exiting the LED device 10 may have the first peak wavelength but with a reduced FWHM.

FIG. 1B is a spectral plot of the LED device 10 of FIG. 1A. The x-axis generally represents wavelength, and the y-axis generally represents intensity of light. A first emission spectrum represents light generated by the LED chip 12 of FIG. 1A, and the first emission spectrum has a first peak wavelength 30 and a first FWHM value 32. A second emission spectrum represents light exiting the LED device 10 of FIG. 1A after passing through the filter structure 26. In certain embodiments, the second emission spectrum is a subset of the first emission spectrum. For example, the second emission spectrum may reside within an area of the intensity versus wavelength curve that defines the first emission spectrum. As illustrated in FIG. 1B, second emission spectrum may have the same or similar first peak wavelength 30, such as a tolerance of one to five nanometers, while a second FWHM value 34 is provided that is less than the first FWHM value 32. This may be accomplished by configuring the filter structure 26 of FIG. 1A as a band-pass filter where a midpoint of the passband is within 5 nm or within 2 nm of the first peak wavelength 30. For illustrative purposes, the second FWHM value 34 is shown just below the first FWHM value 32 with respect to the y-axis. In practice, the second FWHM value 34 could be at a same or similar intensity position as the first FWHM value 32 when the intensity of the first peak wavelength 30 does not substantially change. In other implementations where there may be some light loss attributable to presence of the filter structure 26, the first and second FWHM values 32, 34 could be at different positions relative to the y-axis.

With reference to both FIGS. 1A and 1B, the first emission spectrum generated by the LED chip 12 may be configured such that the first peak wavelength 30 is in a range from 500 nm to 570 nm, and the first FWHM value 32 may be in a range from 32 to 35 nm. The second emission spectrum after light passes through the filter structure 26 may have the same or similar first peak wavelength 30, but with the second FWHM value 34 that is no more than 80% of the first FWHM value 32, or in a range from 70% to no more than 80% of the first FWHM value 32. While the above example is provided in the context of a generally green LED chip, the principles for reducing FWHM values described herein are applicable to other wavelengths, such as blue and red LED chips, without deviating from the principles described. In general, the second FWHM value 32 may be in a range from 50% to no more than 80% of the first FWHM value 34.

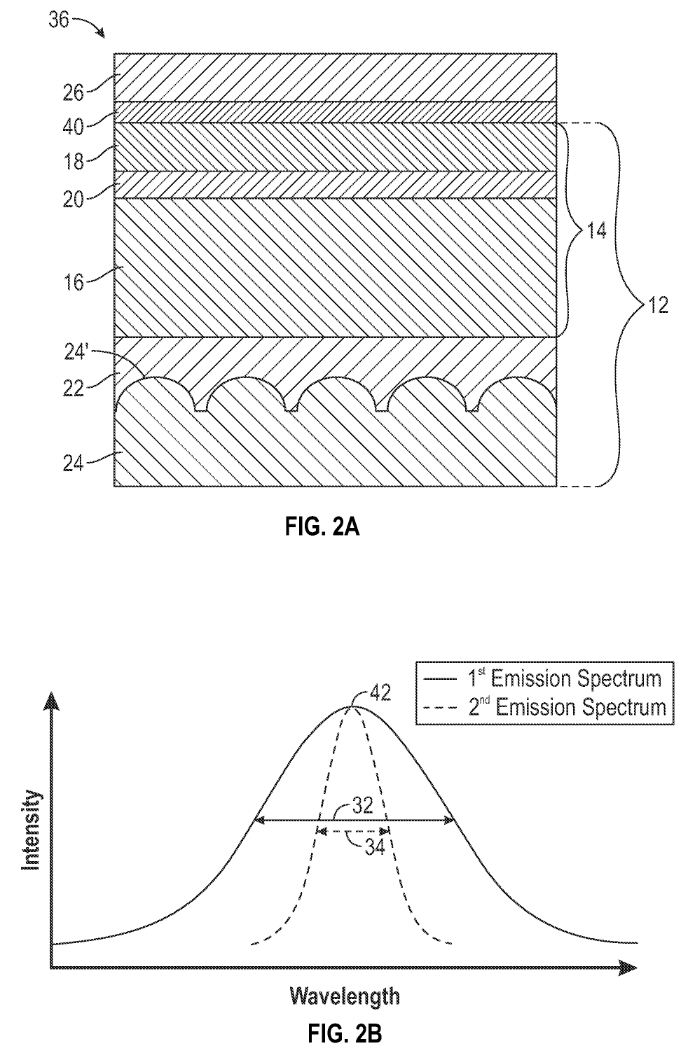

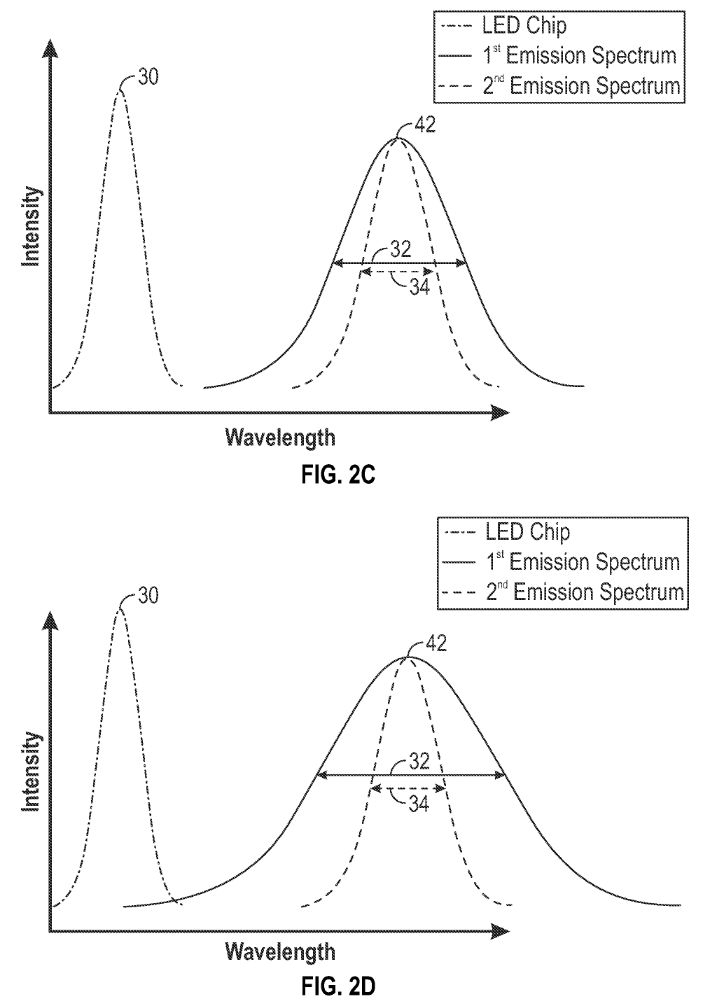

FIG. 2A is a cross-sectional view of an LED device 36 that is similar to the LED device 10 of FIG. 1A for embodiments that further include a lumiphoric material 40. The lumiphoric material 40 is positioned between the active LED structure 14 and the filter structure 26 so that at least a portion of light generated by the active LED structure 14 is subject to wavelength conversion. In certain embodiments, the LED device 36 may be structured as a so-called saturated color device where a majority of light exiting the device has a second peak wavelength provided by the lumiphoric material 40, and little to no perceivable light of the first peak wavelength escapes. In other embodiments, aggregate emissions from the LED device 36 may include a portion of light having a first peak wavelength from the active LED structure 14 in combination with the second peak wavelength provided by the lumiphoric material 40.

FIG. 2B is a spectral plot of the LED device 36 of FIG. 2A. The x-axis generally represents wavelength, and the y-axis generally represents intensity of light. The first emission spectrum for the LED device 36 represents light generated by the LED chip 12 that is subject to wavelength conversion by the lumiphoric material 40 of FIG. 2A. Accordingly, the first emission spectrum has a second peak wavelength 42. The second emission spectrum represents light exiting the LED device 36 of FIG. 2A after passing through the filter structure 26. As illustrated in FIG. 2B, the second peak wavelength 42 may remain the same or be similar, such as a tolerance of one to five nanometers. This may be accomplished by configuring the filter structure 26 of FIG. 2A as a band-pass filter where a midpoint of the passband is equal to the first peak wavelength 30, or within 5 nm or within 2 nm of the first peak wavelength 30. The second FWHM value 34 of the second emission spectrum is provided that is less than the first FWHM value 32 of the first emission spectrum.

With reference to both FIGS. 2A and 2B, the first emission spectrum generated by the LED chip 12 may be generally blue light, such as in a range from 430 nm to 480 nm, and the lumiphoric material 40 may be configured such that the second peak wavelength 42 is in a range from 580 nm to 650 nm for amber and/or red light. As is typical for wavelength-converted emissions, such as when the lumiphoric material 40 comprises phosphors, the first FWHM value 32 is generally large due to broad emissions. The second emission spectrum after light passes through the filter structure 26 may have the same or similar second peak wavelength 42 but with the second FWHM value 34 that is no more than 80% of the first FWHM value 32, or no more than 50%, or in a range from 25% to no more than 50% of the first FWHM value 32. While the above example is provided in the context of a generally amber and/or red emissions, the principles described are applicable to other wavelengths, such as wavelength-converted emissions with peak wavelengths in a range from 480 nm to 650 nm, or in a range from 500 nm to 650 nm, or in a range from 580 nm to 650 nm, including cyan, green, yellow, red, amber, and/or combinations thereof.

FIG. 2C is a spectral plot of the LED device 36 of FIG. 2A for the configuration where a detectable portion of light from the active LED structure 14 is present in the aggregate emissions. With reference to FIGS. 2A and 2C, the aggregate emissions include a combination of light having the first peak wavelength 30 from the active LED structure 14 and light having the second peak wavelength 42 from the lumiphoric material 40. In these embodiments, the filter structure 26 may embody a band-pass filter having a midpoint of a passband at the second peak wavelength 42 or within 5 nm of the second peak wavelength 42. Accordingly, the second emission spectrum that corresponds to light exiting the filter structure 26 exhibits the lower second FWHM value 34 relative to the first FWHM value 32 of wavelength-converted light prior to entering the filter structure 26. By way of example, the first peak wavelength 30 may be in a range from 430 nm to 480 nm, and the second peak wavelength 42 may be above 480 nm, such as in a range from 480 nm to 650 nm. Depending on the lumiphoric material type, the second FWHM value 34 may be in a range from 70% to no more than 80% of the first FWHM value 32, particularly for lumiphoric materials that have generally lower initial FWHM values.

FIG. 2D is a spectral plot of the LED device 36 of FIG. 2A for a configuration similar to FIG. 2C except the first emission spectrum exhibits broader emissions. With reference to FIGS. 2A and 2D, the lumiphoric material 40 may provide broader emissions with a larger first FWHM value 32 compared with FIG. 2C. After passing through the filter structure 26, the second FWHM value 34 may be in a range from 25% to no more than 50% of the first FWHM value 32.

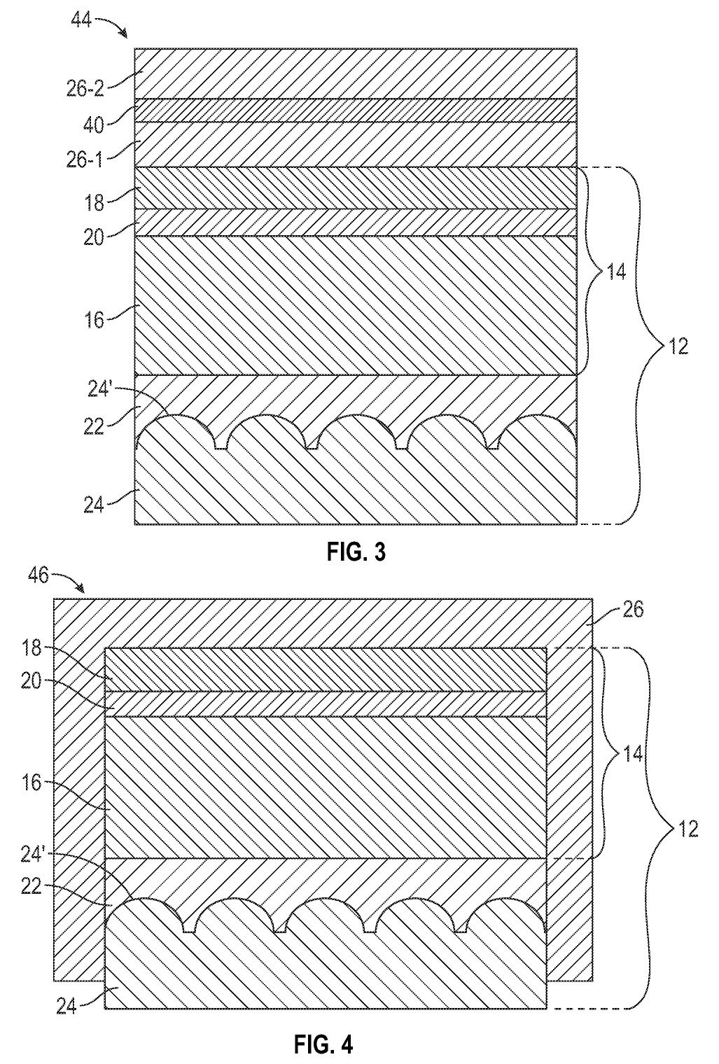

FIG. 3 is a cross-sectional view of an LED device 44 that is similar to the LED device 36 of FIG. 2A for embodiments where the filter structure 26 of FIG. 1A is split into first and second filter structure portions 26-2, 26-2. Rather than combining the structure for a band-pass filter into a single multiple-layer stack, the first filter structure portion 26-1 may be separated from the second filter structure portion 26-2 by the lumiphoric material 40. By way of example, the first filter structure portion 26-1 may provide the upper boundary of the passband, such as embodying a short pass filter, and the second filter structure portion 26-2 may provide the lower boundary of the passband, such as embodying a long pass filter. In such embodiments, the first filter structure portion 26-1 may freely pass light having the first peak wavelength from the active LED structure 14. Any light of the first peak wavelength that reaches the second filter structure portion 26-2 without wavelength conversion may be reflected back to the lumiphoric material 40 for increased wavelength conversion. Moreover, any light of the second peak wavelength from the lumiphoric material 40 that is directed toward the LED chip 12 may be reflected and redirected by the first filter structure portion 26-1 toward a desired emission direction.

FIG. 4 is a cross-sectional view of an LED device 46 that is similar to the LED device 10 of FIG. 1A for embodiments where the filter structure 26 extends on a top surface of the LED chip 12 and on side surfaces of the LED chip 12. By extending the filter structure to cover one or more portions of at least one side surface of the LED chip 12, lateral emissions of the LED chip 12 may also be subject to filtering for reduced FWHM values. This may provide increased uniformity in the FWHM values across a variety of viewing angles. In certain embodiments, the filter structure 26 may embody a preformed structure that is attached to the LED chip 12. The principles described for the shape of the filter structure 26 of FIG. 4 extending along one or more side surfaces of the LED chip 12 may also be implemented in the LED devices of FIGS. 2A and 3.

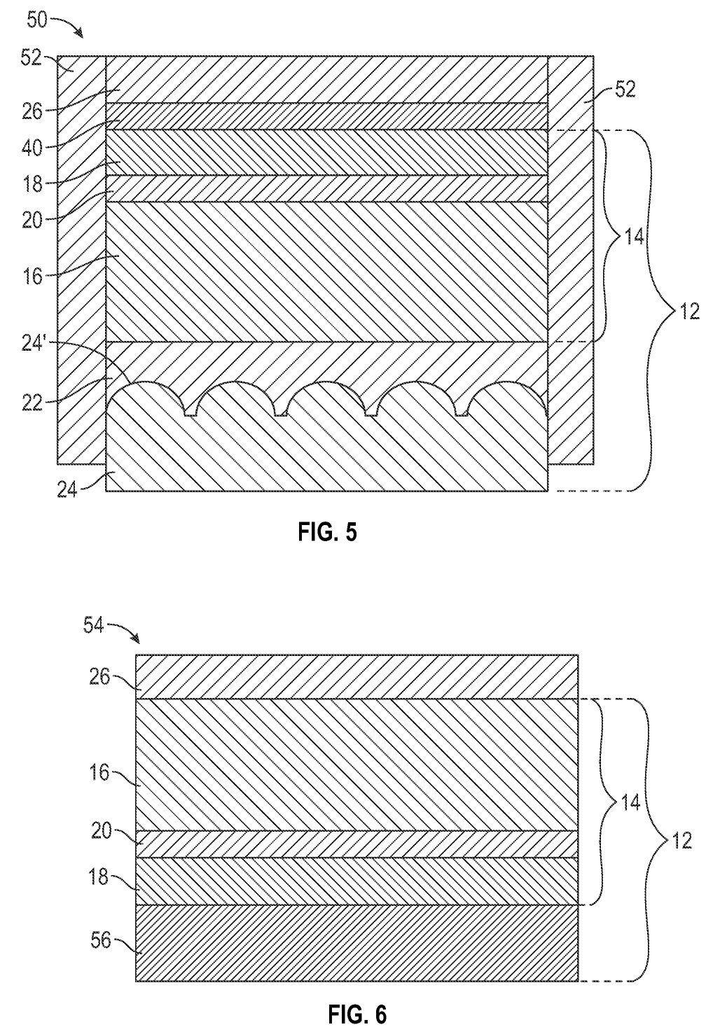

FIG. 5 is a cross-sectional view of an LED device 50 that is similar to the LED device 36 of FIG. 2A for embodiments where the filter structure 26 is positioned on a top surface of the LED chip 12 and a second filter structure 52 is positioned on one or more side surfaces of the LED chip 12. In certain embodiments, the second filter structure 52 comprises a different structure than the first filter structure 26. For example, the second filter structure 52 may be configured to provide a different FWHM value than the first filter structure 26 to adjust for color over angle disparities. In another example, the second filter structure 52 may be configured to reflect light of the first peak wavelength from the active LED structure 14. The principles described for the first and second filter structures 26-1, 26-2 of FIG. 5 may also be implemented in the LED devices of FIGS. 1A to 4.

FIG. 6 is a cross-sectional view of an LED device 54 that is similar to the LED device 10 of FIG. 1A for embodiments where the active LED structure 14 is inverted. In certain embodiments, the active LED structure 14 is transferred to a carrier 56 and the growth substrate 24 of FIG. 1A is removed. For such structures, the p-type layer 18 may be positioned closer to the carrier 56 than the n-type layer 16. In such examples, the filter structure 26 may be formed, or directly formed, as a multiple-layer coating on a surface of the n-type layer 16. The arrangement of the LED device 54 may be implemented in any of the LED devices of FIGS. 1A to 5.

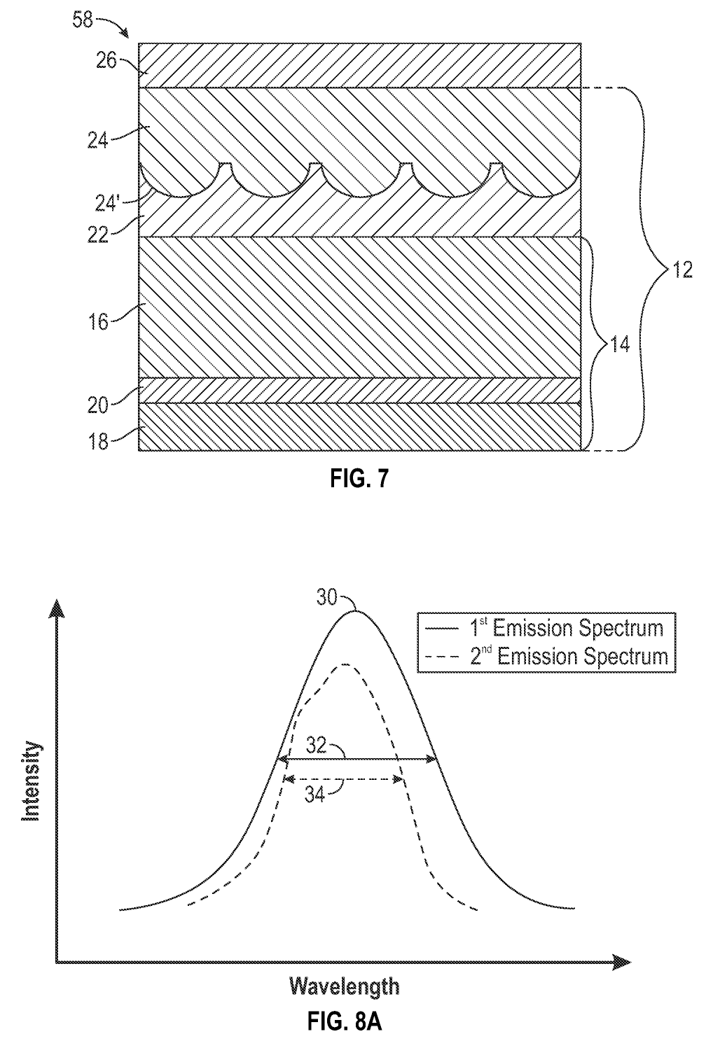

FIG. 7 is a cross-sectional view of an LED device 58 that is similar to the LED device 10 of FIG. 1A for embodiments where the LED chip 12 is a flip-chip LED. For a flip-chip structure, the substrate 24 forms a primary emission surface. Accordingly, the filter structure 26 may be positioned on the substrate 24. By way of example, the filter structure 26 may embody a pre-formed structure that is attached to the LED chip 12. The arrangement of the LED device 58 may be implemented in any of the LED devices of FIGS. 1A to 5.

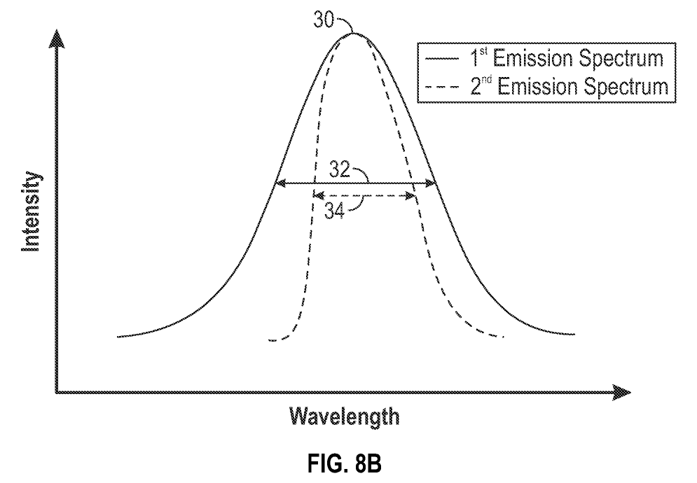

FIG. 8A is a spectral plot for an LED device similar to the LED device 10 of FIG. 1A except the filter structure 26 of FIG. 1A is configured to provide an asymmetric shape for the second emission spectrum. To provide the asymmetric shape relative to the first peak wavelength 30, the passband is shifted so that a midpoint of the passband is offset from the first peak wavelength 30. For example, the midpoint may be offset by more than 5 nm, or in a range from greater than 5 nm to 20 nm, depending on the broadness of the first FWHM value 32. Such asymmetric shape for the second emission spectrum may be useful for color tuning in various applications, such as shifting emissions toward targeted color temperatures while also providing the second FWHM value 34 that is reduced relative to the first FWHM value 32. In the example of FIG. 8A, the second emission spectrum is shifted to lower wavelength portions of the first emission spectrum and at least one shoulder peak is exhibited to the left of the second emission spectrum.

FIG. 8B is a spectral plot for an LED device similar to the LED device 10 of FIG. 1A except the filter structure 26 of FIG. 1A is configured to provide another asymmetric shape for the second emission spectrum. For FIG. 8B, at least a portion of the filter structure 26 of FIG. 1A is configured to be a so-called stronger filter that is capable of filtering a larger percentage of light at certain wavelengths compared to other filters and/or other portions of the same filter. In the example of FIG. 8B, the midpoint of the passband may remain centered at the first peak wavelength 30, but the filter is configured to be stronger for wavelengths that are below the first peak wavelength 30 compared with wavelengths that are above the first peak wavelength 30. This provides a shape of the second emission spectrum that exhibits a steep curve to the left of the first peak wavelength 30 and a more gradual curve to the right of the first peak wavelength 30.

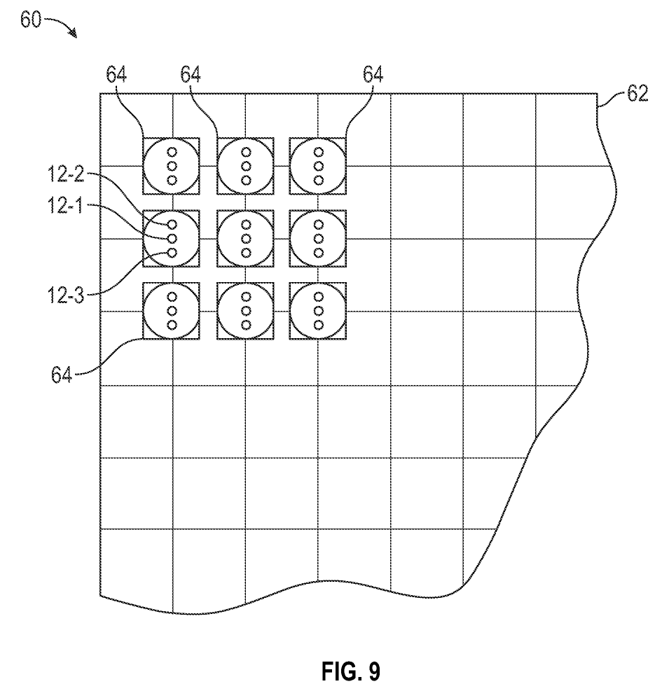

FIG. 9 is a schematic diagram of a portion of an LED device 60, such as a display screen or LED display, for example, an indoor and/or outdoor screen comprising an LED chip or LED package having a filter structure according to principles of the present disclosure. In general terms, the LED device 60 may comprise a larger device that incorporates multiple ones of the LED devices described above with respect to any of FIGS. 1A to 8. The LED device 60 may embody a display panel including a board, such as a driver printed circuit board (PCB) 62 carrying a large number of surface-mount devices (SMDs) 64 arranged in rows and columns, each SMD 64 defining a pixel. The SMDs 64 may embody LED packages with LED devices as described above with respect to any of FIGS. 1A to 8B. The SMDs 64 are electrically connected to traces or pads on the PCB 62 to respond to appropriate electrical signal processing and driver circuitry (not shown). As disclosed above, it is to be appreciated that while FIG. 9 depicts LED chips 12-1 to 12-3 in a linear arrangement within each LED package for the SMD 64, in other embodiments, the LED chips 12-1 to 12-3 may be arranged in different configurations. The LED chips 12-1 to 12-3 of each SMD 64 are adapted to be energized to produce in combination a substantially full range of colors and to define one pixel of the display. Each SMD 64 is configured to be electrically coupled with the signal processing and LED drive circuitry in a manner to selectively energize the array of SMDs 64 and corresponding LED chips 12-1 to 12-3 for producing visual images on said display.

In certain embodiments, each SMD 64 includes three LED chips 12-1 to 12-3, such as a green LED chip 12-1, a red LED chip 12-2, and a blue LED chip 12-3. As described above, the green LED chip 12-1 may sometimes have larger FWHM values than the blue LED chip 12-3 or the red LED chip 12-2 if the red LED chip 12-2 is formed with a different material type than the green and blue LED chips 12-1, 12-3. According to aspects of the present disclosure, a filter structure as described above with respect to any of FIGS. 1A to 8B may be arranged with the green LED chip 12-1 for reducing its FWHM values close to those of the other LED chips 12-2, 12-3. In further embodiments, each of the LED chips 12-1 to 12-3 could be arranged with corresponding filter structures for FWHM reductions of each LED chip 12-1 to 12-3.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device comprising:
an LED chip configured to generate a first emission spectrum of light having a first peak wavelength and a first full width half maximum value; and
a filter structure on the LED chip, the filter structure configured to provide a second emission spectrum of light and a second full width half maximum value that is less than the first full width half maximum value, the second emission spectrum of light being a subset of the first emission spectrum of light.

2. The LED device of claim 1, wherein the first peak wavelength is in a range from 480 nanometers (nm) to 600 nm.

3. The LED device of claim 1, wherein the second full width half maximum value is no more than eighty percent of the first full width half maximum value.

4. The LED device of claim 1, wherein the filter structure comprises a band-pass filter having a midpoint of a passband that is within 5 nm of the first peak wavelength.

5. The LED device of claim 1, wherein the filter structure is positioned on a top surface of the LED chip and on at least one side surface of the LED chip.

6. The LED device of claim 1, wherein the filter structure is a first filter structure positioned on a top surface of the LED chip, and a second filter structure is positioned on at least one side surface of the LED chip.

7. The LED device of claim 1, wherein the LED chip comprises an active LED structure on a carrier such that a p-type layer of the active LED structure is closer to the carrier than an n-type layer of the active LED structure, and the filter structure is on a surface of the n-type layer.

8. The LED device of claim 1, wherein the LED chip comprises an active LED structure on a growth substrate, and the filter structure is on a surface of the growth substrate.

9. The LED device of claim 1, wherein the filter structure forms a band-pass filter having a midpoint of a passband that is greater than the second peak wavelength by at least 5 nm.

10. The LED device of claim 1, wherein the second emission spectrum of light comprises an asymmetric shape.

11. A light-emitting diode (LED) device comprising:
an LED chip configured to generate light of a first peak wavelength;
a lumiphoric material arranged to convert at least a portion of the light of the first peak wavelength to light with a second peak wavelength that different than the first peak wavelength, the LED chip and the lumiphoric material providing a first emission spectrum of light having the second peak wavelength and a first full width half maximum value; and
a filter structure on the LED chip, the filter structure configured to provide a second emission spectrum of light having a second full width half maximum value that is less than the first full width half maximum value, the filter structure comprising a band-pass filter having a midpoint of a passband that is within 5 nm of the second peak wavelength.

12. The LED device of claim 11, wherein the second full width half maximum value is no more than fifty percent of the first full width half maximum value.

13. The LED device of claim 12, wherein the second full width half maximum value is in a range from twenty-five percent to no more than fifty percent of the first full width half maximum value.

14. The LED device of claim 11, wherein the second peak wavelength is in a range from 480 nm to 650 nm.

15. The LED device of claim 11, wherein the filter structure comprises a first filter structure portion and a second filter structure portion that are separated by the lumiphoric material.

16. The LED device of claim 15, wherein the first filter structure portion comprises a short pass filter configured to pass the light of the first peak wavelength and reflect light of the second peak wavelength, and the second filter structure portion comprises a long pass filter configured to pass the light of the second peak wavelength and reflect light of the first peak wavelength.

17. The LED device of claim 11, wherein the filter structure is positioned on a top surface of the LED chip and on at least one side surface of the LED chip.

18. The LED device of claim 11, wherein the filter structure is a first filter structure positioned on a top surface of the LED chip, and a second filter structure is positioned on at least one side surface of the LED chip.

19. A light-emitting diode (LED) device comprising:
a printed circuit board; and
a plurality of light-emitting diode (LED) packages mounted on the board, at least one LED package of the plurality of LED packages comprising:
a first LED chip configured to generate a first emission spectrum of light having a first peak wavelength in a range from 500 nanometers (nm) to 570 nm and a first full width half maximum value;
a filter structure on the first LED chip, the filter structure configured to provide a second emission spectrum of light in the range from 500 nm to 570 nm and having a second full width half maximum value that is less than the first full width half maximum value;
a second LED chip configured to generate light having a second peak wavelength in a range from 600 nm to 650 nm; and
a third LED chip configured to generate light having a third peak wavelength in a range from 430 nm to 480 nm.

20. The LED device of claim 19, wherein the second full width half maximum value is no more than eighty percent of the first full width half maximum value.

21. The LED device of claim 19, wherein the filter structure comprises a band-pass filter having a midpoint of a passband that is within 5 nm of the first peak wavelength.

22. The LED device of claim 19, wherein the LED device comprises an LED display.
